(19) United States
(12) Patent Application Publication
(10) Pub. No.: US 2015/0140694 A1
(43) Pub. Date: May 21, 2015

(54) GAS SUPPLY DEVICE, FILM FORMING APPARATUS, GAS SUPPLY METHOD, AND STORAGE MEDIUM

(71) Applicant: TOKYO ELECTRON LIMITED, TOKYO (JP)

(72) Inventors: Mitsuya INOUE, Yamanashi (JP); Makoto TAKADO, Iwate (JP)

(21) Appl. No.: 14/548,654

(22) Filed: Nov. 20, 2014

(30) Foreign Application Priority Data
Nov. 20, 2013 (JP) 2013-240041

(51) Int. Cl. C23C 16/52; H01L 21/66; H01L 21/02; C23C 16/448; C23C 16/455

(52) U.S. Cl. CPC C23C 16/52; C23C 16/4481; C23C 16/455; H01L 21/0228; H01L 21/02118; H01L 22/26
USPC 438/14; 118/712

(57) ABSTRACT

A gas supply device for intermittently supplying raw material gas into a film forming process unit that includes a raw material container for accommodating a raw material, a carrier gas supply unit for supplying carrier gas to evaporate the raw material, a raw material gas supply path for supplying the raw material gas and the carrier gas into the film forming process unit, a flow rate detector, a flow rate regulating valve, a raw material supply and block unit for supplying and blocking the raw material gas into the film forming process unit, and a control unit for outputting a control signal for intermittently supplying the raw material gas into the film forming process unit.

### CROSS-REFERENCE TO RELATED APPLICATION

This application claims the benefit of Japanese Patent Application No. 2013-240041, filed on Nov. 20, 2013, in the Japan Patent Office, the disclosure of which is incorporated herein in its entirety by reference.

### TECHNICAL FIELD

The present disclosure relates to a technique for controlling a flow rate of a raw material supplied to a film forming apparatus.

### BACKGROUND

Examples of a method for forming a film on a substrate, such as a semiconductor wafer or the like (hereinafter, referred to as a “wafer”), may include a CVD (Chemical Vapor Deposition) method that forms a film on a wafer by supplying gas serving as a film forming raw material (i.e., raw material gas) onto a surface of the wafer and adsorbing the raw material on the wafer by heating the wafer, an ALD (Atomic Layer Deposition) method that adsorbs an atomic layer or a molecular layer of raw material gas on a surface of a wafer, generates reaction products by supplying reaction gas to oxidize or deoxidize the raw material gas, and deposits a layer of the reaction products by repeating the above processes, and the like.

The film forming raw materials for use in the CVD method and the ALD method often have low vapor pressure. In this case, raw material gas may be obtained by supplying carrier gas into a raw material container which accommodates liquid or solid raw material and evaporating the raw material into the carrier gas. However, an amount of the evaporation of the raw material depends on various factors. The factors include an individual difference between the temperatures of vaporizers which are caused by an individual difference between the states of contact between the vaporizers and apparatuses equipped with the vaporizers, an individual difference between valves installed in pipes connected to the raw material container, a difference in conductance between the pipes which is caused by aging of the valves, and a decrease of the raw material in the raw material container.

To address the variation in the amount of evaporation of the raw material which is caused by the temperature of the vaporizer, it may be considered to measure the amount of evaporation after the vaporizer is replaced, and adjust the temperature based on the amount of evaporation. However, it is hard to correct the variation of the amount of evaporation because of the difference in conductance between the pipes and the decrease of the raw material in the raw material container, and thus, there may be a concern that the amount of evaporation varies, for example, by 4%, due to such factors as above. Such variation in the amount of evaporation may result in fluctuation of quality of films that are formed on wafers.

In addition, in the ALD and CVD methods, in some cases, the time taken from starting intermittent supply of the raw material gas into the reaction container, which stores wafers, to stopping the supply of the raw material gas may be relatively short. Such short time for supplying the raw material makes it difficult to detect a flow rate of the raw material supplied onto wafers, as will be described with respect to embodiments later. Under such circumstances, there is a need of a technique capable of preventing the variation in the amount of evaporation caused by the above-mentioned factors and stabilizing the flow rate of the raw material supplied onto the wafers for each processing for the wafers.

There has been conventionally proposed a technique for forming a film in a semiconductor manufacturing process, in which raw material liquid accommodated in an evaporation unit is evaporated by ejecting (or bubbling) carrier gas with a flow rate regulated by a first mass flow controller, a mass flow of the mixture gas obtained as above is measured by a mass flow meter, and an amount of evaporated raw material liquid is detected based on a difference in mass flow between the carrier gas and the mixture gas. However, this conventional technique does not address the case where the raw material gas is intermittently supplied and the time for supplying the raw material gas per one time is short.

### SUMMARY

Some embodiments of the present disclosure provide a technique for forming a film by intermittently supplying raw material gas consisting of carrier gas and a raw material evaporated by the carrier gas onto a substrate, which is capable of preventing a flow rate of raw material supplied onto the substrate from being unstable for each processing for the substrate.

According to an aspect of the present disclosure, there is provided a gas supply device for intermittently supplying raw material gas into a film forming process unit for subjecting a substrate to a film forming process. The gas supply device includes a raw material container configured to accommodate a solid or liquid raw material, a carrier gas supply unit configured to supply carrier gas to evaporate or sublime the raw material in the raw material container, a raw material gas supply path configured to supply the raw material gas including the evaporated or sublimed raw material and the carrier gas into the film forming process unit, a flow rate detector for the raw material gas and a flow rate regulating valve for the raw material gas, which are installed in the raw material gas supply path, a raw material supply and block unit configured to supply and block the raw material gas into the film forming process unit; and a control unit configured to output a control signal to cause a first process and a second process to be performed when a substrate is loaded into the film forming process unit. The first process includes determining a flow rate of the raw material in the raw material gas based on a flow rate of the carrier gas supplied from the carrier gas supply unit and a flow rate of the raw material gas detected by the flow rate detector and obtaining a degree of opening the flow rate regulating valve with which the flow rate of the raw material is set to be a pre-set value. The second process includes supplying and blocking the raw material gas by using the raw material supply and block unit in order to intermittently supply the raw material gas into the film forming process unit with the degree of opening the flow rate regulating valve being fixed at the obtained degree of opening.

According to another aspect of the present disclosure, there is provided a gas supply method of intermittently supplying raw material gas into a film forming process unit for subjecting a substrate to a film forming process, comprising: vaporizing a raw material accommodated in a raw material container by supplying carrier gas into the raw material container; supplying the raw material gas including the vaporized raw material and the carrier gas from the raw material container onto the substrate via a raw material gas supply path; detecting a flow rate of the raw material gas by using a flow rate detector which is installed in the raw material gas supply path; obtaining a flow rate of the raw material in the raw material gas based on a flow rate of the carrier gas supplied into the raw material container and a flow rate of the raw material gas detected by the flow rate detector; regulating the flow rate of the raw material gas flowing through the raw material gas supply path by regulating a degree of opening a flow rate regulating valve installed in the raw material gas supply path; obtaining the degree of opening the flow rate regulating valve with which the flow rate of the raw material is set to a pre-set value; and supplying and blocking the raw material gas into the film forming process unit in order to intermittently supply the raw material gas into the film forming process unit with the degree of opening the flow rate regulating valve being fixed at the obtained degree of opening, wherein vaporizing the raw material, supplying the raw material gas, detecting the flow rate of the raw material gas, obtaining the flow rate of the raw material in the raw material gas, regulating the flow rate of the raw material gas, obtaining the degree of opening the flow rate regulating valve, and supplying and blocking the raw material gas are performed when the substrate is loaded into the film forming process unit.

According to another aspect of the present disclosure, there is provided a non-transitory computer-readable storage medium storing a computer program used for a gas supply device configured to supply raw material gas into a film forming process unit for subjecting a substrate to a film forming process, wherein the program is organized with instructions for performing the aforementioned gas supply method.

According to another aspect of the present disclosure, there is provided a film forming apparatus including the aforementioned gas supply device and the film forming process unit.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 illustrates an overall configuration of a film forming apparatus including a gas supply device, according to the present disclosure.

FIG. 2 schematically illustrates a configuration of a mass flow controller in the gas supply device.

FIG. 3 shows a processing step performed by the film forming apparatus.

FIG. 4 shows a processing step performed by the film forming apparatus.

FIG. 5 shows a processing step performed by the film forming apparatus.

FIG. 6 shows a processing step performed by the film forming apparatus.

FIG. 7 shows a processing step performed by the film forming apparatus.

FIG. 8 shows a processing step performed by the film forming apparatus.

FIG. 9 shows a processing step performed by the film forming apparatus.

FIG. 10 shows a processing step performed by the film forming apparatus.

FIG. 11 is a chart showing timings of supplying various gases in the film forming apparatus.

FIG. 12 illustrates a graphical view of gas flow rates measured using an apparatus substantially similar to the film forming apparatus

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

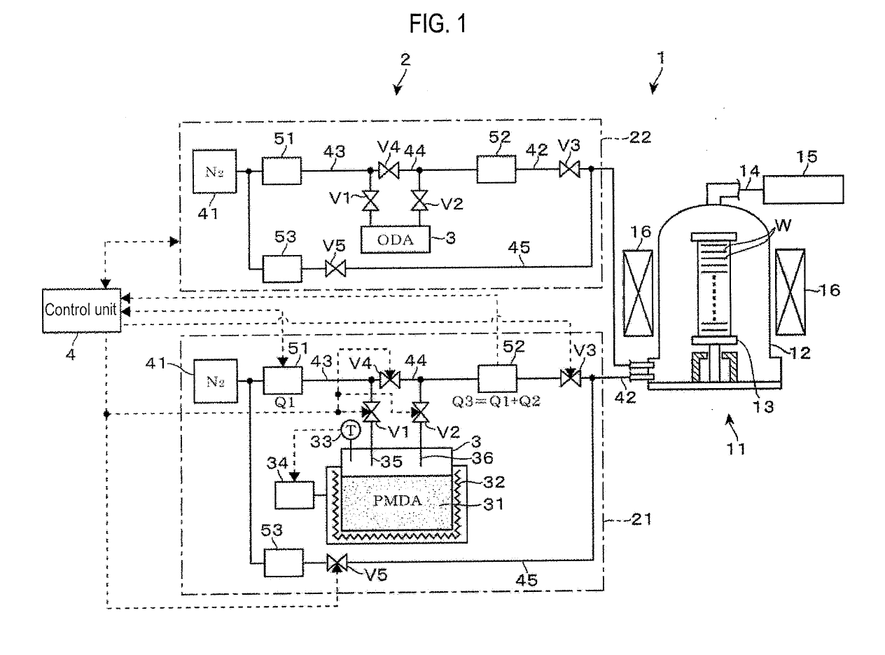

A configuration example of a film forming apparatus 1 including a gas supply device according to the present disclosure is described below with reference to FIG. 1. The film forming apparatus 1 includes a film forming process unit 11 for subjecting a substrate such as a wafer W to a film forming process employing a CVD method, and a gas supply device 2 for supplying raw material gas into the film forming process unit 11.

The film forming process unit 11, which constitutes a main body of a batch-type CVD apparatus, loads a wafer boat 13, in which a plurality of wafers W is mounted, into a vertical reaction container 12, and exhausts an interior of the reaction container 12 through an exhaust line 14 by using a vacuum exhaust unit 15 such as a vacuum pump or the like. The raw material gas is then introduced from the gas supply device 2, and a film forming process is performed by heating the wafers W using a heater 16 installed outside the reaction container 12.

The gas supply device 2 supplies a first monomer consisting of bifunctional acid anhydride, such as PDMA (pyromellitic dianhydride), and a second monomer consisting of bifunctional amine, such as ODA (4,4′-diaminodiphenylether), onto the wafers W. The first and second monomers react with each other on surfaces of the wafers W to form a polyimide film as an insulating film.

The gas supply device 2 includes a gas supply system 21 and a gas supply system 22 for supplying PDMA and ODA, respectively, into the reaction container 12. The gas supply system 21 includes a raw material container 3 accommodating PDMA as a raw material of polyimide, and a gas supply source 41 for supplying nitrogen (N₂) gas as carrier gas into the raw material container 3. An example of the carrier gas may include inert gas, such as helium gas, as well as the N₂ gas.

The gas supply system 21 further includes a raw material gas supply path 42, a carrier gas supply path 43, a gas flow path 44, and a gas supply path 45. The raw material gas supply path 42 connects the raw material container 3 to the reaction container 12, and supplies the raw material gas (including sublimed PMDA and the carrier gas), which is obtained from the raw material container 3, to the film forming process unit 11. The carrier gas supply path 43 connects the gas supply source 41 to the raw material container 3.

The raw material container 3 is a container that accommodates PDMA as a solid raw material 31 and is surrounded with a jacket-shaped heater 32 including a resistive heating element. The raw material container 3 can regulate an internal temperature of the raw material container 3, for example, by changing an amount of electric power fed from an electric power feeder 34 based on a temperature of a vapor phase portion in the raw material container 3 that is detected by a temperature detector 33. The temperature of the heater 32 is set to be in a range of temperature in which PDMA is sublimed but not decomposed, for example, to 250 degrees C.

In the vapor phase portion above the solid raw material 31 in the raw material container 3 is opened with a carrier gas nozzle 35 for introducing the carrier gas from the gas supply source 41 into the raw material container 3, and also opened with a draw nozzle 36 for drawing the raw material gas from the raw material container 3. The carrier gas nozzle 35 forms a downstream end portion of the carrier gas supply path 43 and the draw nozzle 36 forms an upstream end portion of the raw material gas supply path 42. The raw material gas drawn from the raw material container 3 is supplied into the reaction container 12 via the raw material gas supply path 42. An interior of the raw material container 3 is vacuum-exhausted by the vacuum exhaust unit 15 via the reaction container 12 and the raw material gas supply path 42, and is maintained at a decompressed atmosphere.

An MFC (Mass Flow Controller) 51 and a valve V1 are disposed in the carrier gas supply path 43 toward a downstream portion of the carrier gas supply path 43, in that order. A valve V2, an MFC 52, and a valve V3 are disposed in the raw material gas supply path 42 toward a downstream portion of the raw material gas supply path 42, in that order. A valve V4 is disposed in the gas flow path 44. An upstream end portion of the gas flow path 44 is connected between the MFC 51 and the valve V1 in the carrier gas supply path 43, and a downstream end portion of the gas flow path 44 is connected between the valve V2 and the MFC 52 in the raw material gas supply path 42.

An MFC 53 and a valve V5 are disposed in the gas supply path 45 toward a downstream portion of the gas supply path 45, in that order. An upstream end portion of the gas supply path 45 is connected between the gas supply source 41 and the MFC 51 in the carrier gas supply path 43, and a downstream end portion of the gas supply path 45 is connected to a downstream portion of the valve V3 of the raw material gas supply path 42. The gas supply path 45 and the MFC 53 serve to dilute the raw material gas drawn from the raw material container 3 to a predetermined concentration by using the N₂ gas supplied from the gas supply source 41 before the raw material gas is supplied into the reaction container 12.

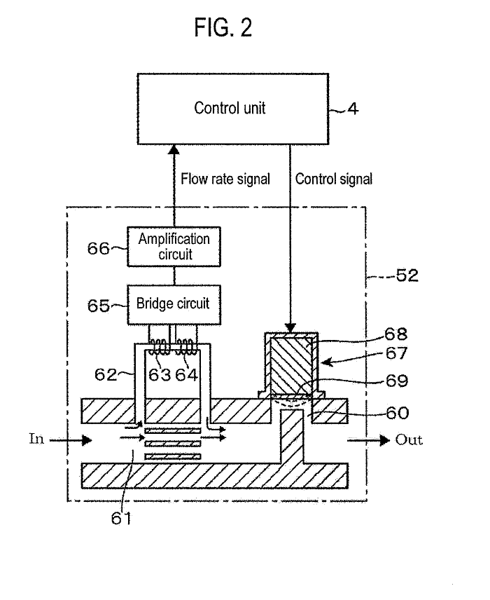

The MFC 52 disposed in the raw material gas supply path 42 is described below with reference to a schematic configuration view of FIG. 2. The MFC 52 includes a main flow path 61 and a thin pipe unit 62 having two end portions, both of which are connected to the main flow path 61. Resistors 63 and 64 are wound around a pipe wall of the thin pipe unit 62 at upstream and downstream positions, respectively. The MFC 52 also includes a bridge circuit 65 and an amplification circuit 66 for detecting a change in resistance of the resistors 63 and 64 as a change in temperature of the pipe wall of the thin pipe unit 62 due to gas flowing through the thin pipe unit 62, and converting the detected change in resistance into a gas flow rate signal. The gas flow rate signal is outputted to a control unit 4 which will be described later. The control unit 4 measures a flow rate of the gas flowing through the MFC 52 based on the gas flow rate signal. As such, the MFC 52 is configured to include a thermal-type MFM (Mass Flow Meter) as a flow rate detector.

A bent passage 60 and a valve (specifically, flow rate regulating valve) 67 for regulating a gas flow rate at the bent passage 60 are formed at a more downstream position of the main flow path 61 than where the thin pipe unit 62 is connected. Thus, the flow rate of the gas supplied from the MFC 52 is regulated depending on a degree of opening the valve 67. The valve 67 includes an actuator 68 formed by a piezoelectric element, and a diaphragm 69 transformed by the actuator 68. The control unit 4 supplies a control voltage to the actuator 68. Based on the control voltage, the piezoelectric element of the actuator 68 is transformed, which in turn bends the diaphragm 69. The bent diaphragm 69 is indicated by dotted lines in FIG. 2. The bent passage 60 is narrowed by the bent diaphragm 69. As such, the degree of opening the valve 67 corresponds to an amount of bending the diaphragm 69, and thus, is controlled by controlling how much the diaphragm 69 is bent based on the control voltage.

The MFCs 51 and 53 are configured in the same manner as the MFC 52. The degree of opening the valve 67 in the MFC 51 is controlled based on a flow rate signal outputted from the MFC 51 such that the flow rate of the carrier gas flowing through the MFC 51 is set to be a predetermined value. In a similar manner, in the MFC 53, the amount of the gas supplied to a downstream portion is controlled to a predetermined value. The control of the MFC 52 will be described later.

The second gas supply system 22 is configured in the same manner as the first gas supply system 21. In FIG. 1, the same elements as the first gas supply system 21 are denoted by the same reference numerals, and explanation for the elements is omitted. ODA as a liquid raw material for polyimide, instead of PMDA, is accommodated in the raw material container 3 of the second gas supply system 22. The raw material gas consisting of vaporized ODA gas and carrier gas, which is supplied from the raw material container 3 into the reaction container 12, is referred to as process gas to be distinguished from the raw material gas containing PMDA.

The film-forming apparatus 1 as configured above (i.e., the film forming process unit 11 and the gas supply device 2) is connected to the control unit 4. The control unit 4 is implemented with a computer including a CPU (not shown) and a storage unit (not shown). The control unit 4 outputs control signals to various components in the film forming apparatus 1 to perform operations of loading the wafer boat 13 into the reaction container 12, vacuum-exhausting the interior of the reaction container 12, forming films by supplying the raw material gas from the gas supply device 2, and unloading the wafer boat 13 after stopping the supply of the raw material gas. Opening and closing each valve, adjusting the degree of opening of each valve, and controlling each flow rate of gas by an MFC are performed based on the control signals. Programs organized with groups of steps (instructions) to operate the film forming apparatus 1 are recorded in the storage unit. The programs are stored in a storage medium such as a hard disk, compact disc, magneto-optical disc, memory card, or the like, and are installed in the computer.

The control unit 4 controls the gas supply systems 21 and 22 to supply the raw material gas alternately and repeatedly from the gas supply systems 21 and 22 onto the wafers W in the reaction container 12 to form a polyimide film. The gas supply system 21 is controlled to supply the raw material gas into the reaction container 12 according to two control types, i.e., a first control type and a second control type. The gas supply system 21 is controlled according to the first control type for a first supply of the raw material gas onto the wafer W, and according to the second control type for second and further subsequent supplies of the raw material gas.

Given that a carrier gas flow rate that is measured based on the flow rate signal of the MFC 51 is Q1, the valve 67 of the MFC 51 is controlled to set Q1 to a predetermined value. Given that a raw material gas flow rate that is measured based on the flow rate signal outputted from the MFC 52 is Q3, the control unit 4 can calculate a PDMA flow rate (i.e., flow rate of evaporated raw material) Q2 (=Q3−Q1) based on the flow rates Q1 and Q3. In the first control type, the degree of opening the valve 67 in the MFC 52 is adjusted to set the flow rate of evaporated raw material Q2 to a predetermined value. As such, the first control type is a feedback control to set the flow rate of evaporated raw material Q2 to the predetermined value by controlling the degree of opening of the valve 67 in the MFC 52 based on the raw material gas flow rate Q3 and the carrier gas flow rate Q1.

However, in the first supply of the raw material gas onto the wafer W, since a relatively long time period is taken for the carrier gas to be supplied into the raw material container 3 in order to stabilize an evaporation amount of PMDA (here, the evaporation is construed to include sublimation) every time the raw material gas is supplied, a time period for supplying the raw material gas into the reaction container 12 is set to be relatively long. Accordingly, in the first supply of the raw material gas, while the raw material gas is supplied, the raw material container 3 can be filled with the carrier gas, which is then delivered to the MFC 52, and thus, the evaporation amount of PMDA in the raw material container 3 can also be stabilized. As a result, the value Q2 (=Q3−Q1), after a predetermined time period since the supply of the raw material gas has started, has a highly-precise association with the evaporation amount of PMDA that is actually supplied into the reaction container 12. Further, as will be shown in experiments below, the values Q3 and Q2 are stabilized when the degree of opening the valve 67 in the MFC 52 is constant. Accordingly, by performing the feedback control, the flow rate of evaporated raw material Q2 can be adjusted to the predetermined value so that an effect on the flow rate of evaporated raw material caused by a temperature of a vaporizer, conductance of pipes, and conditions of consuming raw material can be cancelled.

By contrast, in the second and further subsequent supplies of the raw material gas, a time period for supplying the raw material gas into the film forming process unit 11 is set to be shorter than the time period for the first supply of the raw material gas in order to improve a throughput and to curb waste of the raw material. When the time period for supplying the raw material gas into the film forming process unit 11 is short, the time period for supplying the raw material gas may expire before the carrier gas passes through the MFC 51, fills the raw material container 3, and is delivered to the MFC 52. Therefore, there may be a concern that a difference between the flow rate of evaporated raw material Q2 calculated by (Q3−Q1) and an actual flow rate of evaporated raw material may increase, i.e., the actual flow rate of evaporated PMDA may not be set to the predetermined value even using the feedback control.

In addition, in the second and further subsequent supplies of the raw material gas, while the raw material gas is supplied, the evaporation amount of PMDA may not be stabilized and the carrier gas may not reach the MFC 52, as described above. Therefore, as will be shown in experiments below, when the degree of opening the valve 67 in the MFC 52 is constant, the values Q3 and Q2 may continue to vary for the time period for supplying the raw material gas. If the feedback control is performed in the case where the value Q2 continuously varies, the flow rate of PMDA actually supplied into the reaction container 12 is varied depending on responsiveness to a control signal of the valve 67 of the MFC 52. More specifically, the value Q2 may or may not be hunted depending on the responsiveness of the MFC 52 in the film forming apparatus 1, and the flow rate of PMDA supplied into the reaction container 12 may be varied depending on individual film forming apparatuses 1. For this reason, it may not be a good method to feedback-control the valve 67 of the MFC 52 in the second and further subsequent supplies of the raw material gas.

Accordingly, while the first control type is performed for the first supply of the raw material gas, at a time point when a predetermined time period elapses since the supply of the raw material gas has started, and thus, the degree of opening the valve 67 in the MFC 52 is stabilized, the control unit 4 stores the control voltage supplied to the actuator 68 of the valve 67 in a storage included in the control unit 4. In the second and further subsequent supplies of the raw material gas according to the second control type, the stored control voltage continues to be supplied to the actuator 68 to fix the degree of opening the valve 67 in the MFC 52, and the raw material gas is supplied into the reaction container 12 with the fixed degree of opening.

In this manner, in the second control type, the valve 67 is fixed with a degree of opening that is set to obtain a desired flow rate of evaporated raw material Q2. Thus, the degree of opening the valve 67 is prevented from being varied depending on the varying value Q2. By fixing the degree of opening of the valve 67, it is possible to prevent the flow rate of PMDA supplied into the reaction container 12 from significantly deviating from a desired flow rate while preventing the flow rate of PMDA from being varied depending on the responsiveness to the control signal from the control unit 4, which may be different for different MFCs 52. For the second gas supply system 22, without performing the first and second control types, a predetermined amount of the carrier gas is supplied into the raw material container 3 to evaporate ODA, and the process gas consisting of the carrier gas and evaporated ODA is supplied onto the wafers W.

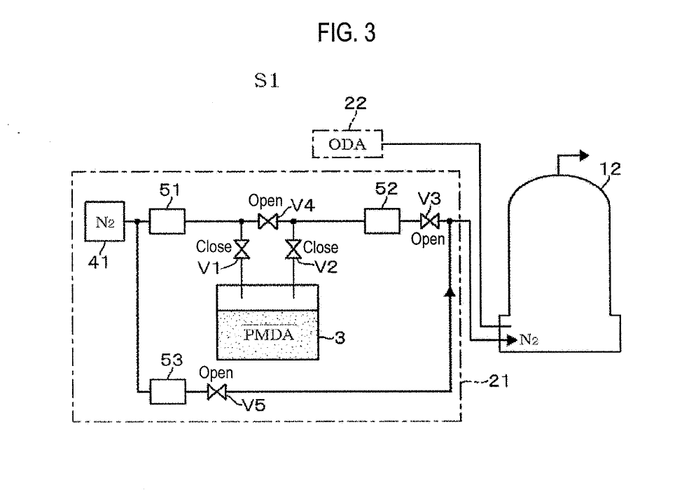

Subsequently, a method for forming the polyimide film using the film forming apparatus 1 is described below with reference to FIGS. 3 to 11 that illustrate processes. Initially, the wafer boat 13, in which a plurality of wafers W mounted, is loaded into the reaction container 12 that is heated by the heater 16 to a temperature at which the polyimide film is formed, for example, to 100 degrees C. to 250 degrees C., specifically, 150 degrees C. to 200 degrees C. (see FIG. 1). Then, an internal pressure of the reaction container 12 is adjusted by the vacuum exhaust unit 15 to a predetermined degree of vacuum and the wafer boat 13 is rotated around a vertical axis by a rotation mechanism (not shown).

With the valve V5 of the gas supply system 21 opened, the N₂ gas is supplied from the gas supply source 41 into the reaction container 12 via the gas supply path 45. The valve V5 is always in an opened state while the wafers W are processed. The valve V4 is then opened and a pressure of a flow path in the upstream side of the valve V4 is adjusted. In this process, the valves V1 and V2 are in a closed state to prevent the carrier gas from being supplied from the MFC 51 into the raw material container 3 (Step S1, FIG. 3). In Step S1, the valve V3 may be in an open state.

After, for example, 2 seconds since the valve V4 is opened, the valve V4 is closed and the valves V1 and V2 are opened. With a delay of a few seconds after opening the valves V1 and V2, the carrier gas is supplied from the MFC 51 into the raw material container 3. A flow rate of the carrier gas is adjusted by the MFC 51 to a preset flow rate Q1, for example, within a range of 50 to 300 sccm. The carrier gas is supplied into the raw material container 3, PDMA is evaporated (or vaporized), and the raw material gas consisting of evaporated PDMA and the carrier gas is flown from the raw material container 3 through the raw material gas supply path 42 toward its downstream portion to be supplied into the reaction container 12 after being diluted with the N₂ gas flowing from the gas supply path 45.

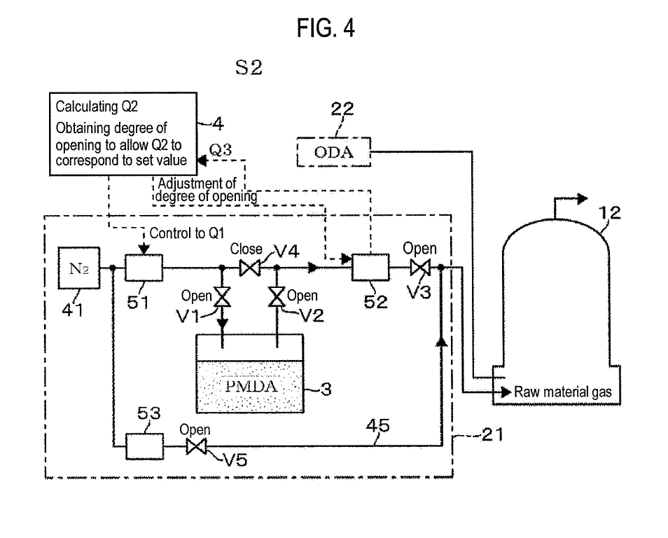

Based on the flow rate signal outputted from the MFC 52 in the raw material gas supply path 42, the control unit 4 obtains the raw material gas flow rate Q3 of the raw material gas supply path 42, calculates the flow rate of evaporated PDMA Q2 (=Q3−Q1), and controls the degree of opening the valve 67 in the MFC 52 such that Q2 corresponds to a preset flow rate, for example, within a range of 40 to 150 sccm (Step S2, FIG. 4). As such, the above-described first control type is performed in Step S2.

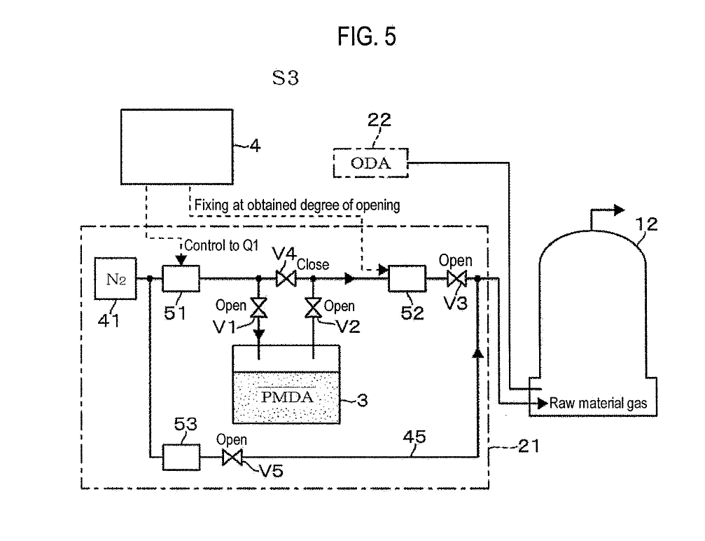

As described above, the supply of the carrier gas into the raw material container 3 is maintained for a relatively long time so that the measured flow rate Q3 can be stabilized, the flow rate of evaporated raw material Q2, which is calculated based on the measured flow rate Q3, can also be stabilized, and the control voltage for the valve 67 of the MFC 52 can be maintained constant. After, for example, 40 seconds after the valves V1 and V2 are opened, the control unit 4 stores the control voltage in the storage and the control voltage continues to be outputted to the MFC 52. Thus, the degree of opening the valve 67 is fixed and is not adjusted (Step S3, FIG. 5). As such, the second control type is performed in Step S3. Molecules of PMDA contained in the raw material supplied into the reaction container 12 are deposited on the surface of the wafer W to form a layer of PMDA.

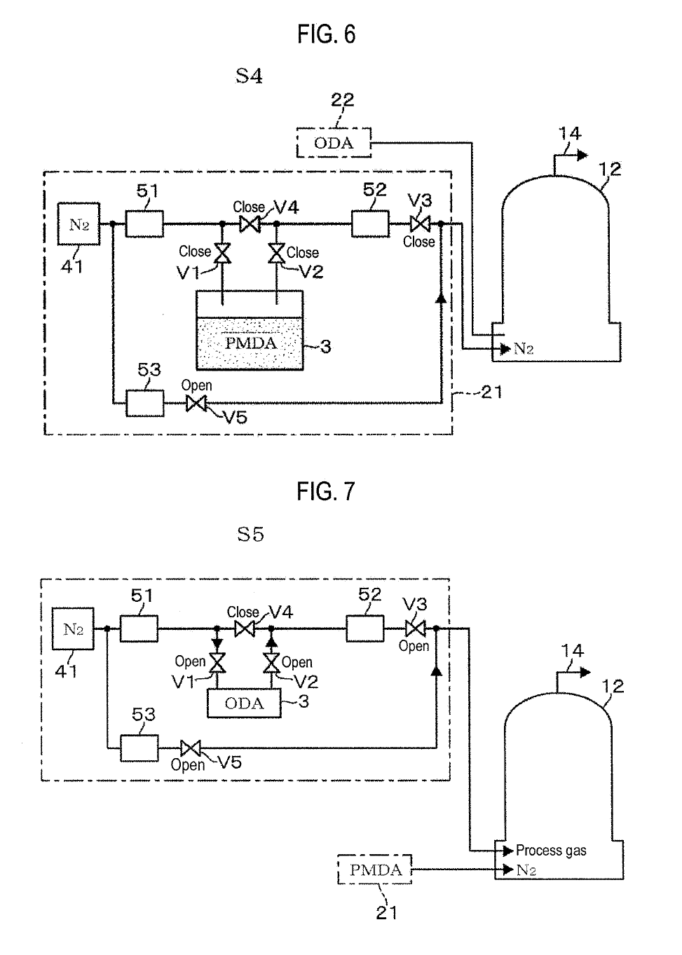

After, for example, 15 seconds after the control voltage is stored, the supply of the carrier gas from the MFC 51 is stopped, the valves V1, V2, and V3 are closed, and the supply of the raw material gas into the reaction container 12 is stopped. With the valve V5 still opened, the N₂ gas is supplied into the reaction container 12. The raw material gas remaining in the reaction container 12 is purged with the N₂ gas and removed through the exhaust line 14. This purging process is maintained, for example, for 10 seconds (Step S4, FIG. 6).

Thereafter, the valves V1, V2, V3, and V5 of the second gas supply system 22 are changed from a closed state to an opened state, and the carrier gas is supplied to ODA in the raw material container 3. ODA is evaporated (or vaporized) and the process gas including the carrier gas and the ODA gas is drawn from the raw material container 3 and is supplied into the reaction container 12 after being diluted by the N₂ gas from the gas supply path 45 (Step S5, FIG. 7).

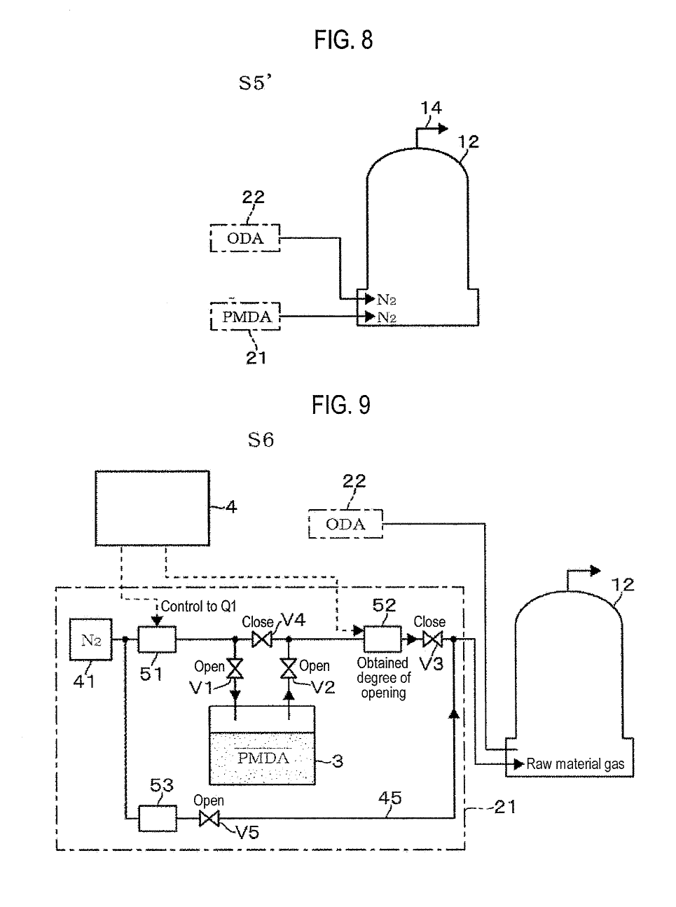

ODA in the process gas reacts with PMDA on the surface of the wafer W to form a thin layer of polyimide. After the process gas is supplied from the second gas supply system 22 for a predetermined time, the valves V1 and V2 are closed, the supply of the carrier gas into the raw material container 3 is stopped, and the supply of the process gas into the reaction container 12 is stopped. With the valves V3, V4, and V5 opened, the N₂ gas is supplied into the reaction container 12. The process gas remaining in the reaction container 12 is purged with the N₂ gas and is removed through the exhaust line 14 (Step S5′, FIG. 8). After the N₂ gas is supplied from the second gas supply system 22 for a predetermined time, the valves V3, V4, and V5 are closed.

Thereafter, the valves V1 and V2 of the first gas supply system 21 are opened. After a small delay since the valves V1 and V2 are opened, the carrier gas is supplied into the raw material container 3, and PMDA is evaporated. In this process, the MFC 51 is controlled so that the carrier gas flows through the MFC 51 with the same flow rate Q1 as those in Steps S2 and S3. The valve 67 is the MFC 52 is opened with the degree of opening that was obtained in Step S2. In addition, since the valve V3 forming a supply end portion at the downstream portion of the MFC 52 is in a closed state, the raw material gas is retained in the upstream portion of the valve V3 (Step S6, FIG. 9). The reason for fixing the degree of opening the valve 67 of the MFC 52 in Step S6 without feedback-controlling the valve 67 as described above is to prevent the degree of opening the valve 67 from being increased. Otherwise, if the feedback-controlling is performed, the degree of opening the valve 67 would be increased at the moment when the supply of the raw material gas into the reaction container 12 is started in subsequent Step S7 under a state where the supply of raw material gas has been stopped. As such, fixing the degree of opening makes it possible to prevent a mass flow rate of the raw material gas from being introduced into the reaction container 12 due to an excessive degree of opening.

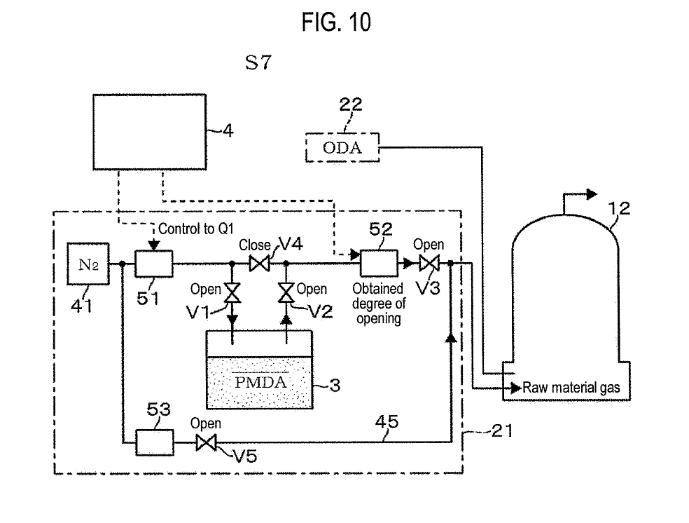

After, for example, 3 seconds after the valves V1 and V2 are opened, the valve V3 is opened and the raw material gas is supplied into the reaction container 12 (Step S7, FIG. 10). The degree of opening of the valve 67 of the MFC 52 is maintained at the obtained degree of opening. PMDA supplied onto the wafer W is deposited on the thin layer of polyimide formed on the wafer W, in a similar manner as described above with respect to Steps S2 and S3. Similar to Step S3, for example, after 15 seconds after the valve V3 is opened, the supply of the carrier gas from the MFC 51 is stopped, and the valves V1, V2, and V3 are closed to stop the supply of the raw material gas into the reaction container 12. As such, Step S7 performs the same operation as Step S3.

As described with the second control type, in Step S7, the time period for the supply of the raw material gas is short, the precision of the association between the actual flow rate of evaporated PMDA and the flow rate Q2 (i.e., the difference between the flow rate Q3 measured in the MFC 52 and the carrier gas flow rate Q1 set in the MFC 51) may be lower than that in the case where the time period for the supply of the raw material gas is long, and the calculated value Q2 may be unstable. Accordingly, the degree of opening the valve 67 in the MFC 52 is fixed without performing the feedback control of the valve 67 in the MFC 52 based on Q2.

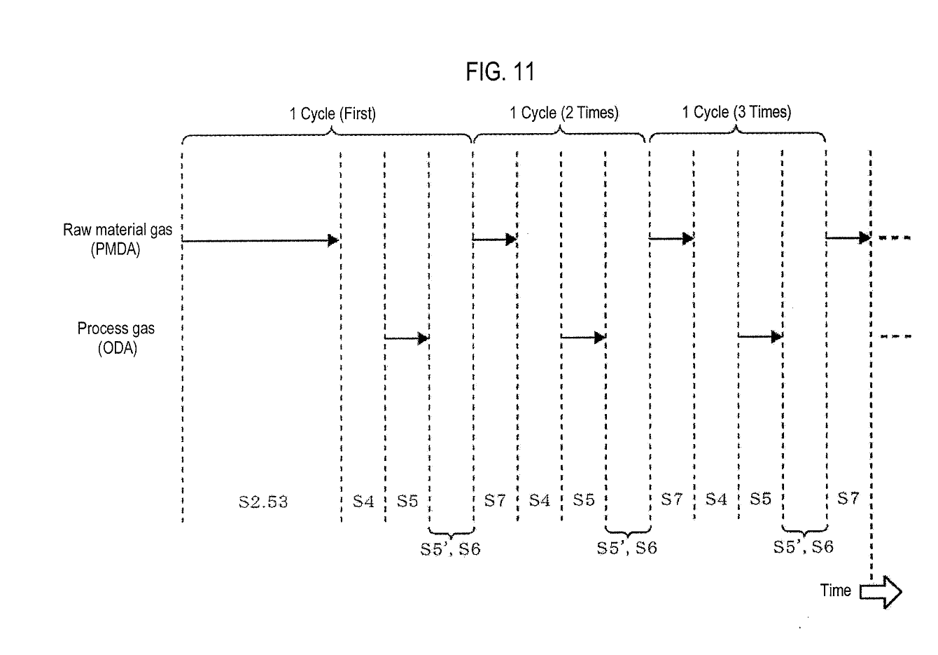

After Step S7, processes from Step S4 to Step S7 are repeatedly performed. FIG. 11 is a chart that illustrates timings at which the raw material gas containing PDMA and the process gas containing ODA are supplied and timings at which the steps are performed. When the steps are performed as described above, the raw material gas and the process gas are supplied alternately and repeatedly into the reaction container 12. Given that one cycle includes processes of supplying the raw material gas, exhausting the raw material gas, supplying the process gas, and exhausting the process gas forms, this cycle is repeated, for example, about 100 times. Thus, the polyimide layers are stacked on the wafer W to form a polyimide film having a predetermined thickness. Then, the wafer boat 13 is unloaded from the reaction container 12.

When the wafer boat 13, in which next wafers W are mounted, is loaded into the reaction container 12, a series of steps starting from Step Si is performed to form a polyimide film as described above. In this case, the degree of opening the valve 67 in the MFC 52 is newly obtained in Step S2 subsequent to Step S1 and the valve 67 is fixed with the obtained degree of opening in Steps S3 and S7. The reason for obtaining the degree of opening as changed above is that when the raw material in the raw material container 3 decreases as described above, the amount of evaporation is varied and the degree of opening of the valve 67 for achieving the flow rate of evaporated raw material Q2 as a set value is also varied. Thus, in this film forming apparatus 1, the Steps S1 to S7 are performed every time the wafers W are loaded.

With the film forming apparatus 1, in the supply of the raw material gas at a first cycle in which the time period for supplying the raw material is set to be long, the flow rate of evaporated PMDA Q2 is calculated based on the raw material flow rate Q3 detected by the MFC 52 and the carrier gas flow rate Q1 set in the MFC 51, and the degree of opening the valve 67 in the MFC 52 having the flow rate of evaporated PMDA Q2 as a set value is obtained. At second and further subsequent cycles in which the time period for supplying the raw material is set to be short, the valve 67 is fixed at the degree of opening obtained in the first cycle and the raw material gas is supplied. The above operation is performed every time the wafers W are loaded into the reaction container 12. By supplying the raw material gas with the degree of opening obtained in the manner as above, it is possible to prevent the flow rate of evaporated PMDA, which is supplied onto the wafers W, from being deviated from a desired flow rate. In addition, by fixing the degree of opening, it is possible to prevent the flow rate of evaporated PMDA from being varied depending on the responsiveness of the MFC 52. As a result, the flow rate of evaporated PMDA supplied into the reaction container 12 for each processing is stabilized. Thus, it is possible to prevent a quality of a polyimide film formed on each wafer W from being varied in each processing.

The time period for supplying the raw material at the second and further subsequent cycles is 15 seconds in the above example but may be set to be shorter, for example, several seconds. In the above example, the second gas supply system 22 may be controlled according to the above-described first and second control types, similar to the first gas supply system 21. The film forming raw material is not limited to the above example. For example, when the polyimide film is formed as in the above example, CBDA (1,2,3,4-cyclobutane tetracarboxylic acid dianhydride), CHDA (cyclohexane-1,2,4,5-tetracarboxylic acid dianhydride), or the like may be used instead of PMDA. In addition, NDA (5-carboxymethylbicyclo[2.2.1]heptane-2,3,6-tricarboxylic acid 2,3: 5,6-dianhydride) may be used instead of ODA. In addition, the present disclosure may be applied to an apparatus for performing an ALD method.

The piezoelectric element forming the actuator 68 has a hysteresis. Thus, an amount of deflection of the diaphragm 69 when the control voltage (i.e., driving voltage) is lowered from a certain voltage (e.g., a positive side voltage), which is larger than a target voltage to be applied to the actuator 68, to the target voltage is different from that when the control voltage is raised from a certain voltage (e.g., a negative side voltage), which is smaller than the target voltage, to the target voltage. Therefore, even when the same control voltage is applied to the actuator 68, the degree of opening of the valve 67 may be varied. In order to prevent the degree of opening from being varied, it may be determined in advance in the MFC 52 whether to lower the positive side voltage to the target voltage or raise the negative voltage to the target voltage, before the control voltage is applied as determined. Whether to change the control voltage to the target voltage from the positive side voltage or the negative side voltage is determined based on a pre-evaluation on the film forming apparatus 1 before processing the wafers W.

In addition, even when the control voltage applied to the valve 67 is constant, the degree of opening the valve 67 in the MFC 52 may be varied depending on a change in ambient temperature of the MFC 52 during the film forming processing, and thus, the flow rate of PMDA supplied into the reaction container 12 may be varied. In order to prevent such variation of the flow rate of PMDA, a temperature sensor may be installed around the MFC 52 and a cooling mechanism may also be installed in the MFC 52. An example of the cooling mechanism may include a Peltier element and a cooling fan. The control unit 4 is configured to detect the ambient temperature based on an output signal from the temperature sensor. If the ambient temperature exceeds a target value while the above-described film forming cycles are performed, the control unit 4 actuates the cooling mechanism such that the ambient temperature lies below the target value.

In the above example, after obtaining the degree of opening the valve 67 in the MFC 52, the degree of opening of the valve 67 is fixed and the valve V3 at a secondary side of the MFC 52 is opened and closed to control the supply and the stop of the raw material gas into the reaction container 12. Alternatively, when the supply of the raw material gas into the reaction container 12 is stopped, the valve 67 in the MFC 52 may be closed to stop the supply of raw material gas into the reaction container 12, and when the raw material gas is supplied into the reaction container 12, the valve 67 may be opened to supply the raw material gas into the reaction container 12.

In the above example, the MFC 52 includes the valve 67 for regulating the flow rate in the raw material gas supply path 42 and the MFM for measuring the flow rate in the raw material gas supply path 42, both of which are integrated. Alternatively, without integrating the MFM and the valve 67, the MFM and the valve 67 may be separately installed in the raw material gas supply path 42. The actuator 68 of the valve 67 is not limited to the piezoelectric element but may include a solenoid, a motor, or the like. The valve 67 is not limited to the diaphragm-type valve as long as a degree of opening of the valve can be regulated. For example, the valve 67 may include a needle valve, a butterfly valve or the like.

### Experiment 1

A film forming apparatus for experiment (i.e., a film forming apparatus configured substantially similar to the above-described film forming apparatus 1) was used to record the carrier gas flow rate Q1 and the raw material gas flow rate Q3 measured when wafers W were subjected to a process according to the above embodiments. The flow rate of evaporated raw material Q2 (=Q3−Q1) calculated based on Q1 and Q3 was also recorded. However, unlike the film forming apparatus 1, the experimental film forming apparatus uses an MFM, instead of the MFC 52, to measure the raw material gas flow rate Q3. Unlike the MFC 52, the MFM does not include the valve 67 whose degree of opening is changed according to a control signal from the control unit 4. Therefore, in Experiment 1, since the degree of opening the valve 67 in the MFC 52 is not adjusted in Step S2 (unlike the embodiment using the above-described film forming apparatus 1), the process is performed with the same degree of opening the valve 67 fixed in Steps S2, S3, and S7.

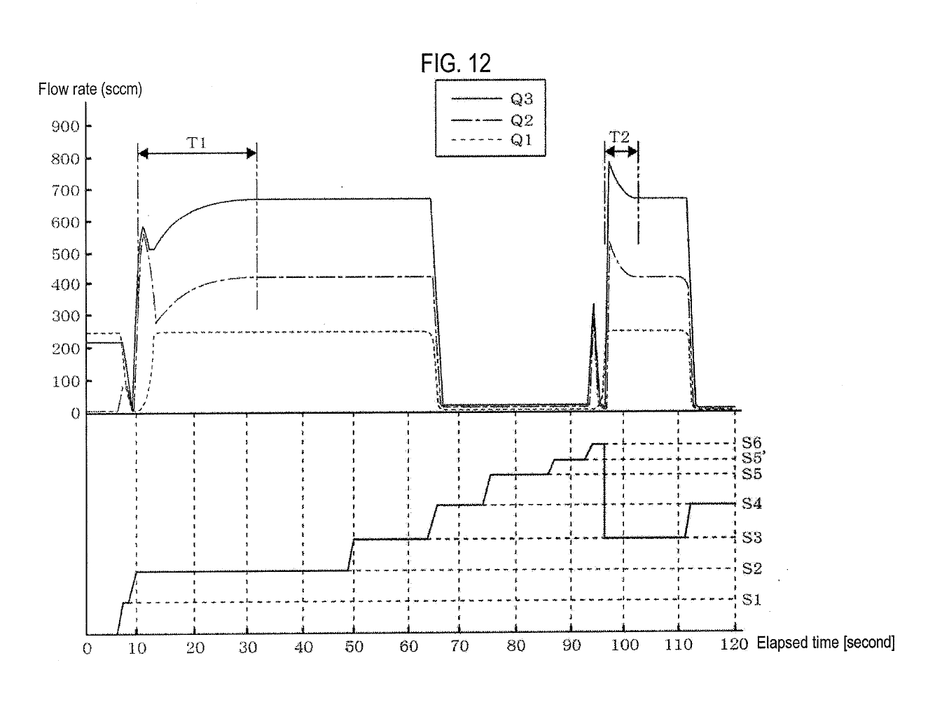

FIG. 12 is a graph showing changes in Q1, Q2, and Q3, in which the flow rate Q1 is indicated by a dotted line, the flow rate Q2 is indicated by a dot-and-dash line, and the flow rate Q3 is indicated by a solid line. In the graph, a horizontal axis represents time [seconds] elapsed from a predetermined timing and a vertical axis represents a gas flow rate [sccm]. In addition, timings at which the above-described steps are performed are shown in FIG. 12. However, Step S7 provides the same operation as Step S3. Although in the above example, Step S3 in the second and subsequent cycles was described as being separated from Step S7, Step S7 is expressed by Step S3 in FIG. 12 for the sake of convenience. The reason why Q2 and Q3 is temporarily raised and then lowered, immediately after Step S2 is started, is that the raw material gas retained in a passage is introduced into the MFM by opening the valve. After Q2 and Q3 are lowered, Q2 and Q3 are slowly raised and become stable. The time (indicated by T1 in FIG. 12) required from the start of Step S2 to the stabilization of Q2 and Q3 is about 20 seconds.

The reason why Q2 and Q3 are raised and unstable up to the 20 seconds after Step S2 is started is that it takes time for the carrier gas, whose flow rate is measured by the MFC 51, to reach the MFM and it takes time for the amount of evaporated PMDA to be stable, as described previously. Because Q2 and Q3 become stable 20 seconds after Step S2 is started, it is believed that the MFC 52 may be installed, instead of the MFM, and Q2 can be adjusted to a set value by performing the feedback control until the Q2 and Q3 become stable, thereby preventing variation of the amount of evaporation due to the factors described in the “BACKGROUND” section.

In second Step S3 (i.e., Step S7), Q2 and Q3 are temporarily raised immediately after Step S3 is started. The reason why Q2 and Q3 are raised is that the raw material gas, which is retained in the passage at an upstream portion of the MFM during Step S6, is flown into the MFM. Q2 and Q3 are lowered after being raised as above and become stable after 4 second after Step S3 is started. The time taken from the start of Step S3 to stabilization is indicated by T2 in FIG. 12. In second Step S3, the graph shows that the time taken for Q2 and Q3 to be stable is short, unlike Step S2. If a feedback control for the degree of opening the valve 67 in the MFC 52 is performed based on Q2 varying, as discussed in the embodiment, Q2 is varied depending on the responsiveness of the MFC 52. Thus, variations occur between film forming apparatuses 1. Accordingly, in the second and further subsequent Step S3 (or Step S7), it may be effective to fix the degree of opening of the valve 67 of the MFC 52, as shown in the embodiment, without performing the feedback control.

According to the present disclosure in some embodiments, a flow rate of the raw material in the raw material gas is obtained based on a flow rate of the carrier gas and a flow rate of the raw material gas, and a degree of opening a flow rate regulating valve in which the flow rate of the raw material controlled to be a preset value is obtained. Next, the flow rate regulating valve is fixed at the obtained degree of opening and the raw material gas is intermittently supplied into a film forming process unit. This operation is repeated every time a substrate is loaded into the film forming process unit. This makes it possible to prevent a flow rate of the raw material supplied onto a substrate from being unstable for each processing for the substrate. As a result, it is possible to prevent the quality of a film formed on the substrate from fluctuating.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such fauns or modifications as would fall within the scope and spirit of the disclosures.

What is claimed is:

1. A gas supply device for intermittently supplying raw material gas into a film forming process unit for subjecting a substrate to a film forming process, comprising:
a raw material container configured to accommodate a solid or liquid raw material;
a carrier gas supply unit configured to supply carrier gas to evaporate or sublime the raw material in the raw material container;
a raw material gas supply path configured to supply the raw material gas including the evaporated or sublimed raw material and the carrier gas into the film forming process unit;
a flow rate detector for the raw material gas and a flow rate regulating valve for the raw material gas, which are installed in the raw material gas supply path;
a raw material supply and block unit configured to supply and block the raw material gas into the film forming process unit; and
a control unit configured to output a control signal to cause a first process and a second process to be performed when the substrate is loaded into the film forming process unit, the first process including determining a flow rate of the raw material in the raw material gas based on a flow rate of the carrier gas supplied from the carrier gas supply unit and a flow rate of the raw material gas detected by the flow rate detector and obtaining a degree of opening the flow rate regulating valve with which the flow rate of the raw material is set to be a pre-set value, and the second process including supplying and blocking the raw material gas by using the raw material supply and block unit in order to intermittently supply the raw material gas into the film forming process unit with the degree of opening the flow rate regulating valve being fixed at the obtained degree of opening.

2. The gas supply device of claim 1, wherein a mass flow controller for the carrier gas, which sets a flow rate of the carrier gas to a pre-set value, is installed in a carrier gas supply path between the carrier gas supply unit and the raw material container, and the flow rate of the carrier gas used in the first process is set to be the pre-set value of the mass flow controller.

3. The gas supply device of claim 1, wherein the flow rate detector for the raw material gas and the flow rate regulating valve for the raw material gas are constituted with a mass flow controller for the raw material gas.

4. A film forming apparatus comprising:
the gas supply device of claim 1; and
the film forming process unit.

5. The film forming apparatus of claim 4, further comprising a gas supply unit configured to supply process gas, which is different from the raw material gas, into the film forming process unit, alternately with the raw material gas.

6. A gas supply method of intermittently supplying raw material gas into a film forming process unit for subjecting a substrate to a film forming process, comprising:
vaporizing a raw material accommodated in a raw material container by supplying carrier gas into the raw material container;
supplying the raw material gas including the vaporized raw material and the carrier gas from the raw material container onto the substrate via a raw material gas supply path;
detecting a flow rate of the raw material gas by using a flow rate detector which is installed in the raw material gas supply path;
obtaining a flow rate of the raw material in the raw material gas based on a flow rate of the carrier gas supplied into the raw material container and a flow rate of the raw material gas detected by the flow rate detector;
regulating the flow rate of the raw material gas flowing through the raw material gas supply path by regulating a degree of opening a flow rate regulating valve installed in the raw material gas supply path;
obtaining the degree of opening the flow rate regulating valve with which the flow rate of the raw material is set to a pre-set value; and
supplying and blocking the raw material gas into the film forming process unit in order to intermittently supply the raw material gas into the film forming process unit with the degree of opening the flow rate regulating valve being fixed at the obtained degree of opening,
wherein vaporizing the raw material, supplying the raw material gas, detecting the flow rate of the raw material gas, obtaining the flow rate of the raw material in the raw material gas, regulating the flow rate of the raw material gas, obtaining the degree of opening the flow rate regulating valve, and supplying and blocking the raw material gas are performed when the substrate is loaded into the film forming process unit.

7. The gas supply method of claim 6, further comprising supplying process gas, which is different from the raw material gas, into the film forming process unit, alternately with the raw material gas.

8. A non-transitory computer-readable storage medium storing a computer program used for a gas supply device configured to supply raw material gas into a film forming process unit for subjecting a substrate to a film forming process, wherein the program is organized with instructions for performing the gas supply method of claim 6.
